(19) United States
(12) Patent Application Publication
(10) Pub. No.: US 2016/0276147 A1
(43) Pub. Date: Sep. 22, 2016

(54) Silicon Nitride Film Forming Method and Silicon Nitride Film Forming Apparatus

(71) Applicant: TOKYO ELECTRON LIMITED, Tokyo (JP)

(72) Inventor: Hidenobu SATO, Nirasaki City (JP)

(21) Appl. No.: 15/066,494

(22) Filed: Mar. 10, 2016

(30) Foreign Application Priority Data
Mar. 20, 2015 (JP) 2015-058041

(51) Int. Cl. H01L 21/02; C23C 16/34; C23C 16/52; H01L 21/677; C23C 16/455

(52) U.S. Cl. CPC H01L 21/0217; H01L 21/0228; H01L 21/02337; H01L 21/67739; C23C 16/45544; C23C 16/52; C23C 16/345

(57) ABSTRACT

A silicon nitride film forming method includes accommodating a workpiece within a reaction chamber, forming a silicon nitride film on the workpiece accommodated within the reaction chamber, carbon-terminating a surface of the silicon nitride film by supplying a hydrocarbon compound having an unsaturated bond into the reaction chamber accommodating the workpiece on which the silicon nitride film is formed, and unloading the workpiece, on which the silicon nitride film having a carbon-terminated surface is formed, out of the reaction chamber.

### CROSS-REFERENCE TO RELATED APPLICATION

This application claims the benefit of Japanese Patent Application No. 2015-058041, filed on Mar. 20, 2015, in the Japan Patent Office, the disclosure of which is incorporated herein in its entirety by reference.

### TECHNICAL FIELD

The present disclosure relates to a silicon nitride film forming method and a silicon nitride film forming apparatus.

### BACKGROUND

As silicon nitride film forming methods, there have been proposed many different methods in which a high-quality silicon nitride film is formed on a workpiece, for example, a semiconductor wafer, under a low temperature using a chemical vapor deposition (CVD) method or an atomic layer deposition (ALD) method. For example, there is known a method of forming a thin film at a low temperature of 300 to 600 degrees C.

However, a natural oxide film is easily generated on a surface of the silicon nitride film formed. As a result, there is posed a problem in that the wet etching resistance of the surface of the silicon nitride film decreases.

### SUMMARY

Some embodiments of the present disclosure provide a silicon nitride film forming method and a silicon nitride film forming apparatus, which are capable of improving a wet etching resistance.

According to one embodiment of the present disclosure, there is provided a silicon nitride film forming method, including: accommodating a workpiece within a reaction chamber; forming a silicon nitride film on the workpiece accommodated within the reaction chamber; carbon-terminating a surface of the silicon nitride film by supplying a hydrocarbon compound having an unsaturated bond into the reaction chamber accommodating the workpiece on which the silicon nitride film is formed; and unloading the workpiece, on which the silicon nitride film having a carbon-terminated surface is formed, out of the reaction chamber.

According to one embodiment of the present disclosure, there is provided a silicon nitride film forming apparatus, including: a reaction chamber configured to accommodate a workpiece; a film forming gas supply part configured to supply a film forming gas into the reaction chamber; a carbon gas supply part configured to supply a hydrocarbon compound having an unsaturated bond into the reaction chamber; and a control part configured to control the film forming gas supply part and the carbon gas supply part, wherein the control part is configured to have the workpiece accommodated within the reaction chamber, control the film forming gas supply part to form a silicon nitride film on the workpiece accommodated within the reaction chamber, control the carbon gas supply part to carbon-terminate a surface of the silicon nitride film, and unload the workpiece, on which the silicon nitride film having a carbon-terminated surface is formed, out of the reaction chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a film forming apparatus according to an embodiment of the present disclosure.

FIG. 2 is a view illustrating a configuration of a control part of the film forming apparatus illustrated in FIG. 1.

FIG. 3 is a view illustrating a film forming method.

FIG. 4 is a view illustrating a relationship between a carbon purge gas and an etching amount.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

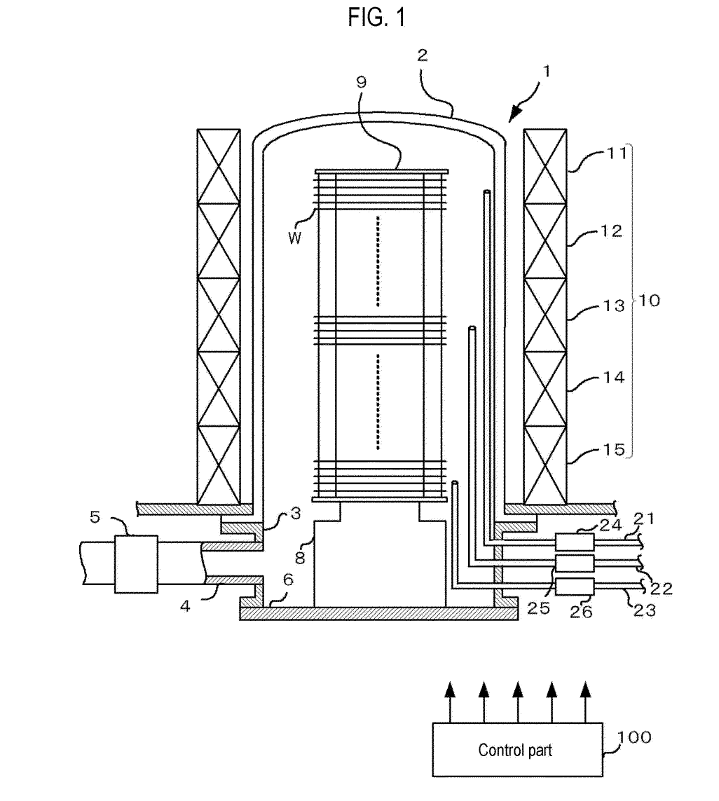

Hereinafter, descriptions will be made on a silicon nitride film forming method and a silicon nitride film forming apparatus according to an embodiment of the present disclosure. In the present embodiment, there will be described, as an example, a case where a batch-type vertical heat treatment apparatus is used as the silicon nitride film forming apparatus of the present disclosure. In FIG. 1, there is illustrated a configuration of a heat treatment apparatus according to the present embodiment.

As illustrated in FIG. 1, the heat treatment apparatus 1 includes a substantially cylindrical reaction tube 2 having a ceiling. The reaction tube 2 is disposed so that the longitudinal direction thereof is oriented in a vertical direction. The reaction tube 2 is made of a material superior in heat resistance and corrosion resistance, for example, quartz.

A substantially cylindrical manifold 3 is installed under the reaction tube 2. The upper end of the manifold 3 is air-tightly joined to the lower end of the reaction tube 2. An exhaust pipe 4 for exhausting a gas existing within the reaction tube 2 is air-tightly connected to the manifold 3. A pressure regulating part 5 formed of a valve control part 125, a vacuum pump 126 and the like, which will be described later, is installed in the exhaust pipe 4. The pressure regulating part 5 is configured to regulate the internal pressure of the reaction tube 2 to a desired pressure (vacuum level).

A lid 6 is disposed below the manifold 3 (the reaction tube 2). The lid 6 is made of a material superior in heat resistance and corrosion resistance, for example, quartz. The lid 6 is configured to be moved up and down by a boat elevator 127 which will be described later. The lid 6 is disposed so that if the lid 6 is moved up by the boat elevator 127, the lower side (furnace opening portion) of the manifold 3 (the reaction tube 2) is closed, while the lower side (furnace opening portion) of the reaction tube 2 is opened if the lid 6 is moved down by the boat elevator 127.

A heat-insulating cylinder 8 configured to prevent a reduction of the internal temperature of the reaction tube 2 in the furnace opening portion of the reaction tube 2 is mounted on the lid 6. A wafer boat 9 is mounted on the heat-insulating cylinder 8. The wafer boat 9 is made of, for example, quartz. The wafer boat 9 is configured to accommodate a plurality of semiconductor wafers W with a predetermined gap left therebetween in the vertical direction. Furthermore, a rotary table configured to rotatably support the wafer boat 9 which accommodates the semiconductor wafers W may be installed on the heat-insulating cylinder 8. The wafer boat 9 may be mounted on the rotary table. In this case, it becomes easy to control the semiconductor wafers W accommodated in the wafer boat 9 at a uniform temperature.

A heater part 10 formed of, for example, a resistance heating element, is installed around the reaction tube 2 so as to surround the reaction tube 2. The interior of the reaction tube 2 is heated to a predetermined temperature by the heater part 10. As a result, the semiconductor wafers W are heated to a predetermined temperature. The heater part 10 is formed of heaters 11 to 15 disposed at, for example, five stages. Below-described power controllers are respectively connected to the heaters 11 to 15. By independently supplying electric power to the respective power controllers, it is possible to independently heat the heaters 11 to 15 to desired temperatures.

Furthermore, a plurality of process gas supply pipes configured to supply a process gas into the reaction tube 2 is installed in the manifold 3. In FIG. 1, there are illustrated three process gas supply pipes 21 to 23 which supply a process gas to the manifold 3.

Flow rate control parts 24 to 26 are respectively installed in the respective process gas supply pipes 21 to 23. As will be described later, each of the flow rate control parts 24 to 26 is formed of a mass flow controller (MFC) 124 which adjusts the flow rate of the process gas flowing through each of the process gas supply pipes 21 to 23. Thus, the process gases supplied from the process gas supply pipes 21 to 23 are respectively supplied into the reaction tube 2 after the flow rates of the process gases are adjusted to desired flow rates by the flow rate control parts 24 to 26.

Examples of the process gases supplied from the process gas supply pipes 21 to 23 may include a source gas, a nitriding gas, a dilution gas, a purge gas and a carbon purging gas.

The source gas may be a Si source which causes a source (Si) to be adsorbed onto a workpiece. The source gas is supplied in an adsorption step which will be described later. In this example, dichlorosilane (DCS) is used as the Si source.

The nitriding gas may be a gas which nitrides the adsorbed source (Si). The nitriding gas is supplied in a nitriding step which will be described later. In this example, ammonia (NH₃) is used as the nitriding gas.

The dilution gas is a gas which dilutes the source gas, the nitriding gas or the like. For example, nitrogen (N₂) is used as the dilution gas. The purge gas is a gas which exhausts the gas existing within the reaction tube 2. For example, nitrogen (N₂) is used as the purge gas.

The carbon purging gas is a gas which carbonizes (carbon-terminates) the surface of a silicon nitride film as formed. For example, a hydrocarbon compound having an unsaturated bond is used as the carbon purging gas. Examples of the hydrocarbon compound having an unsaturated bond may include ethylene (C₂H₄), propylene (C₃H₆) and acetylene (C₂H₂).

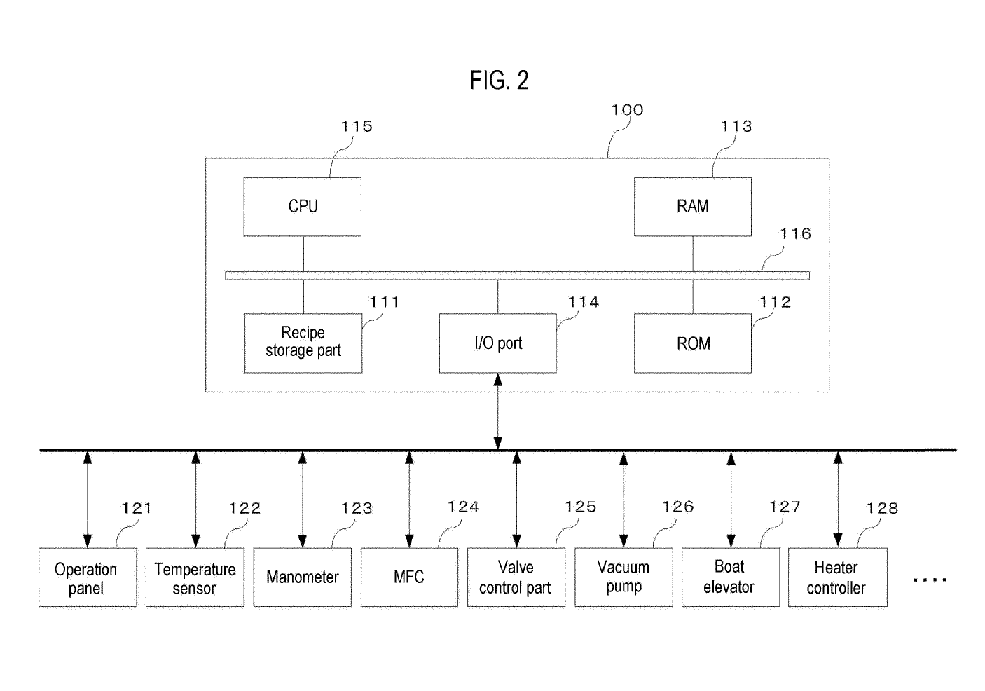

Furthermore, the heat treatment apparatus 1 includes a control part (controller) 100 for controlling process parameters such as a gas flow rate within the reaction tube 2, an internal pressure of the reaction tube 2, a temperature of a processing atmosphere, and the like. In FIG. 2, there is illustrated the configuration of the control part 100.

As illustrated in FIG. 2, an operation panel 121, a temperature sensor 122, a manometer 123, MFCs 124, valve control parts 125, a vacuum pump 126, a boat elevator 127, a heater controller 128 and the like are connected to the control part 100.

The operation panel 121 includes a display screen and an operation button. The operation panel 121 delivers an operator's operation instruction to the control part 100 and displays different kinds of information coming from the control part 100 on the display screen.

The temperature sensor 122 measures the temperatures of the respective parts such as the interior of the reaction tube 2, the interior of the exhaust pipe 4 and the like and notifies the measured values to the control part 100. The manometer 123 measures the pressures of the respective parts such as the interior of the reaction tube 2, the interior of the exhaust pipe 4 and the like and notifies the measured values to the control part 100.

The MFCs 124 are disposed in the respective pipes such as the process gas supply pipes 21 to 23 and the like. The MFCs 124 control the flow rates of the gases flowing through the respective pipes at the flow rates instructed by the control part 100 and measure the actual flow rates of the gases and notifies the measured flow rates to the control part 100.

The valve control parts 125 are disposed in the respective pipes and are configured to control the opening degrees of the valves disposed in the respective pipes at the values instructed by the control part 100. The vacuum pump 126 is connected to the exhaust pipe 4 and is configured to exhaust the gas existing within the reaction tube 2.

The boat elevator 127 loads the wafer boat 9 (the semiconductor wafers W) into the reaction tube 2 by moving the lid 6 upward and unloads the wafer boat 9 (the semiconductor wafers W) from the reaction tube 2 by moving the lid 6 downward.

The heater controller 128 is configured to individually control the heaters 11 to 15. In response to the instruction from the control part 100, the heater controller 128 supplies electric power to the heaters 11 to 15 and heats the heaters 11 to 15. Furthermore, the heater controller 128 individually measures the power consumptions of the heaters 11 to 15 and notifies the measured power consumptions to the control part 100.

The control part 100 includes a recipe storage part 111, a read only memory (ROM) 112, a random access memory (RAM) 113, an input/output (I/O) port 114, a central processing unit (CPU) 115, and a bus 116 which interconnects them.

A setup recipe and a plurality of process recipes are stored in the recipe storage part 111. At the time of initially manufacturing the heat treatment apparatus 1, only the setup recipe is stored in the recipe storage part 111. The setup recipe is executed when generating a thermal model or the like corresponding to each processing apparatus. The process recipes are recipes prepared in a corresponding relationship with heat treatments (processes) actually performed by a user. The process recipes define changes in the temperatures of the respective parts, a change in the internal pressure of the reaction tube 2, start/stop timings for supplying various kinds of gases, supply amounts of various kinds of gases, and the like, during the time period from the loading of the semiconductor wafers W into the reaction tube 2 to the unloading of the processed semiconductor wafers W.

The ROM 112 is a recording medium formed of an electrically erasable programmable read only memory (EEPROM), a flash memory, a hard disc, or the like and configured to store an operation program of the CPU 115, or the like. The RAM 113 serves as a work area of the CPU 115.

The I/O port 114 is connected to the operation panel 121, the temperature sensor 122, the manometer 123, the MFCs 124, the valve control parts 125, the vacuum pump 126, the boat elevator 127, the heater controller 128, and the like and is configured to control the input/output of data or signals.

The CPU 115 constitutes a centrum of the control part 100 and executes a control program stored in the ROM 112. In response to the instruction from the operation panel 121, the CPU 115 controls the operation of the heat treatment apparatus 1 according to the recipes (process recipes) stored in the recipe storage part 111. That is to say, the CPU 115 causes the temperature sensor 122, the manometer 123 and the MFCs 124 to measure the temperatures, the pressures and the flow rates of the respective parts such as the interior of the reaction tube 2, the interior of the exhaust pipe 4, and the like. Based on the measured data, the CPU 115 outputs control signals to the heater controller 128, the MFCs 124, the valve control parts 125, the vacuum pump 126, and the like and controls the respective parts so as to follow the process recipes. The bus 116 delivers information between the respective parts.

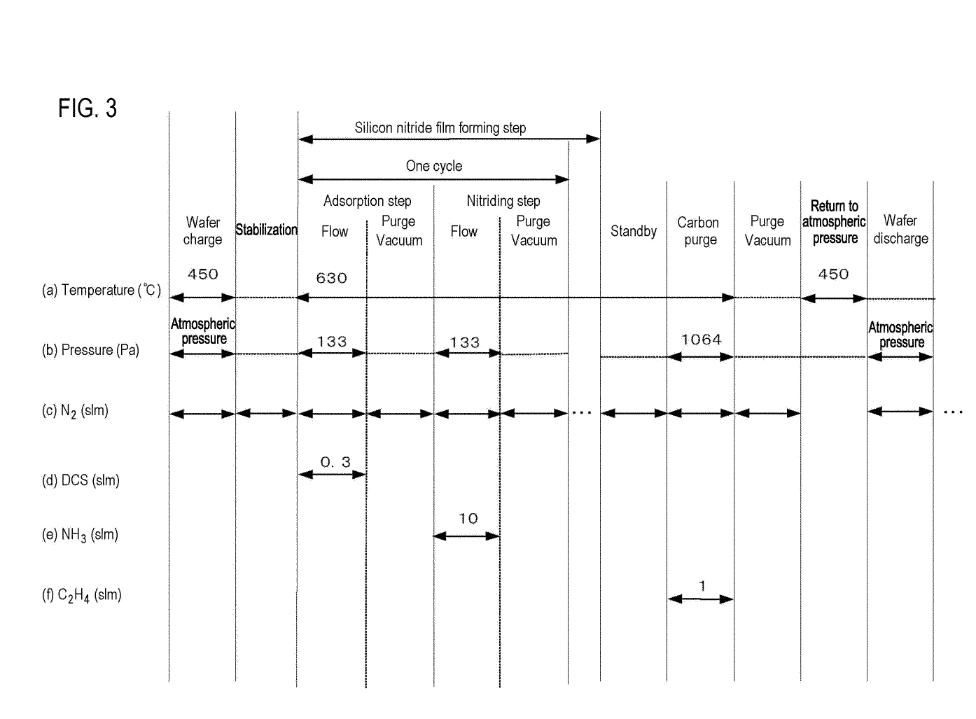

Next, a silicon nitride film forming method using the heat treatment apparatus 1 configured as above will be described with reference to the recipe (time sequence) illustrated in FIG. 3. In the present embodiment, the present disclosure will be described by taking, as an example, a case where a silicon nitride film is formed on a semiconductor wafer W by an ALD method.

As illustrated in FIG. 3, the ALD method according to the present embodiment includes an adsorption step of causing silicon (Si) to be adsorbed on the surface of the semiconductor wafer W and a nitriding step of nitriding the adsorbed Si. These steps constitute one cycle of the ALD method. Furthermore, as illustrated in FIG. 3, DCS is used as a Si source gas, ammonia (NH₃) is used as a nitriding gas, nitrogen (N₂) is used as a dilution gas, and ethylene (C₂H₄) is used as a carbon purging gas. By performing (repeating) the cycle of the recipe illustrated in FIG. 3, multiple times, for example, 100 times, a silicon nitride film having a desired thickness is formed on the semiconductor wafer W.

In the following descriptions, the operations of the respective parts constituting the heat treatment apparatus 1 are controlled by the control part 100 (the CPU 115). The internal temperature of the reaction tube 2, the internal pressure of the reaction tube 2, the flow rates of the gases in each processing are set at the conditions corresponding to the recipe illustrated in FIG. 3 by allowing the control part 100 (the CPU 115) to control the heater controller 128 (the heater part 10), the MFCs 124 (the process gas supply pipe 21, etc.), the valve control parts 125 and the vacuum pump 126 in the aforementioned manner.

First, the interior of the reaction tube 2 is maintained at a predetermined loading temperature, for example, at 450 degrees C. as illustrated in FIG. 3A, by the heater part 10. Subsequently, the wafer boat 9 accommodating the semiconductor wafers W is mounted on the lid 6. Then, the lid 6 is moved up and loaded by the boat elevator 127 to accommodate the semiconductor wafers W (the wafer boat 9) within the reaction tube 2 (wafer charge step).

Subsequently, a silicon nitride film forming step of forming a silicon nitride film on the semiconductor wafer W is performed. First, the interior of the reaction tube 2 is maintained at a predetermined temperature, for example, at 630 degrees C. as illustrated in FIG. 3A, by the heater part 10. Furthermore, a predetermined amount of nitrogen is supplied from the process gas supply pipe 21 or the like into the reaction tube 2 and the gas existing within the reaction tube 2 is exhausted to set the interior of the reaction tube 2 at a predetermined pressure, for example, at 133 Pa (1 Torr) as illustrated in FIG. 3B (stabilization step).

Then, an adsorption step of causing Si to be adsorbed onto the surface of the semiconductor wafer W is performed. The adsorption step is a step at which a source gas is supplied to the semiconductor wafer W to cause Si to be adsorbed onto the surface of the semiconductor wafer W.

At the adsorption step, a predetermined amount of DCS as a Si source is supplied from the process gas supply pipe 21 or the like into the reaction tube 2, for example, at a flow rate of 0.3 slm as illustrated in FIG. 3D, and a predetermined amount of nitrogen is supplied from the process gas supply pipe 21 or the like into the reaction tube 2 as illustrated in FIG. 3C (flow step).

In this regard, the internal temperature of the reaction tube 2 may be set at 450 to 630 degrees C. If the internal temperature of the reaction tube 2 is lower than 450 degrees C., there is a possibility that the silicon nitride film cannot be formed. If the internal temperature of the reaction tube 2 is higher than 630 degrees C., there is a possibility that the film quality or the film thickness uniformity of the silicon film as formed is deteriorated.

The supply amount of DCS may be set at 10 sccm to 10 slm. If the supply amount of DCS is smaller than 10 sccm, there is a possibility that Si is not sufficiently supplied to the surface of the semiconductor wafer W. If the supply amount of DCS is larger than 10 slm, there is a possibility that the amount of Si not contributed to a reaction increases. More specifically, the supply amount of DCS may be 0.1 slm to 3 slm. By setting the supply amount of DCS to fall within this range, it is possible to promote the reaction of Si with the surface of the semiconductor wafer W.

The internal pressure of the reaction tube 2 may be set at 0.133 Pa (0.001 Torr) to 13.3 kPa (100 Torr). By setting the internal pressure of the reaction tube 2 to fall within this range, it is possible to promote the reaction of Si with the surface of the semiconductor wafer W. More specifically, the internal pressure of the reaction tube 2 may be set at 40 Pa (0.3 Torr) to 400 Pa (3 Torr). By setting the internal pressure of the reaction tube 2 to fall within this range, it is easy to control the internal pressure of the reaction tube 2.

The DCS supplied into the reaction tube 2 is heated and activated within the reaction tube 2. Thus, when the DCS is supplied into the reaction tube 2, the activated Si reacts with the surface of the semiconductor wafer W, whereby the Si is adsorbed onto the surface of the semiconductor wafer W.

After a predetermined amount of Si is adsorbed onto the surface of the semiconductor wafer W, the supply of DCS from the process gas supply pipe 21 or the like and the supply of nitrogen from the nitrogen gas supply pipe are stopped. Then, the gas existing within the reaction tube 2 is exhausted. For example, as illustrated in FIG. 3C, a predetermined amount of nitrogen is supplied from the process gas supply pipe 21 or the like into the reaction tube 2, thereby discharging the gas existing within the reaction tube 2 to the outside of the reaction tube 2 (purge and vacuum step).

Subsequently, the interior of the reaction tube 2 is set at a predetermined temperature, for example, 630 degrees C. as illustrated in FIG. 3A, by the heater part 10. Furthermore, as illustrated in FIG. 3C, a predetermined amount of nitrogen is supplied from the process gas supply pipe 21 or the like into the reaction tube 2 and the gas existing within the reaction tube 2 is exhausted to set the internal pressure of the reaction tube 2 at a predetermined pressure, for example, at 133 Pa (1 Torr) as illustrated in FIG. 3B.

Subsequently, a nitriding step of nitriding the surface of the semiconductor wafer W is performed. The nitriding step is a step at which a nitriding gas is supplied onto the semiconductor wafer W to which Si is adsorbed, thereby nitriding the adsorbed Si. In the present embodiment, the adsorbed Si is nitrided by supplying ammonia (NH₃) onto the semiconductor wafer W.

At the nitriding step, a predetermined amount of ammonia is supplied from the process gas supply pipe 21 or the like into the reaction tube 2, for example, at a flow rate of 10 slm as illustrated in FIG. 3E. Furthermore, as illustrated in FIG. 3C, a predetermined amount of nitrogen as a dilution gas is supplied from the process gas supply pipe 21 or the like into the reaction tube 2 (flow step).

In this regard, the supply amount of ammonia may be set at 1 sccm to 50 slm, more specifically 0.1 slm to 20 slm, even more specifically 1 slm to 10 slm. By setting the supply amount of ammonia to fall within this range, it is possible to sufficiently perform nitriding so as to form a silicon nitride film.

The internal pressure of the reaction tube 2 may be set at 0.133 Pa (0.001 Torr) to 13.3 kPa (100 Torr). By setting the internal pressure of the reaction tube 2 to fall within this range, it is possible to promote the nitriding of Si adsorbed onto the surface of the semiconductor wafer W. More specifically, the internal pressure of the reaction tube 2 may be set at 40 Pa (0.3 Torr) to 400 Pa (3 Torr). By setting the internal pressure of the reaction tube 2 to fall within this range, it is easy to control the internal pressure of the reaction tube 2.

If ammonia is supplied into the reaction tube 2, the Si adsorbed onto the semiconductor wafer W is nitrided and a silicon nitride film is formed on the semiconductor wafer W. After the silicon nitride film having a desired thickness is formed on the semiconductor wafer W, the supply of ammonia from the process gas supply pipe 21 or the like is stopped. Furthermore, the supply of nitrogen from the process gas supply pipe 21 or the like is stopped. Then, the gas existing within the reaction tube 2 is exhausted and a predetermined amount of nitrogen is supplied from the process gas supply pipe 21 or the like into the reaction tube 2 as illustrated in FIG. 3C, thereby discharging the gas existing within the reaction tube 2 to the outside of the reaction tube 2 (purge and vacuum step).

Thus, one cycle of the ALD method including the adsorption step and the nitriding step is completed. Subsequently, another cycle of the ALD method starting from the adsorption step is started again. This cycle is repeated a predetermined number of times. Thus, a silicon nitride film having a desired thickness is formed on the semiconductor wafer W.

After the silicon nitride film having a desired thickness is formed on the semiconductor wafer W, the internal temperature of the reaction tube 2 is set at a predetermined temperature, for example, 630 degrees C. as illustrated in FIG. 3A, by the heater part 10. Furthermore, a predetermined amount of nitrogen is supplied from the process gas supply pipe 21 or the like into the reaction tube 2 and the gas existing within the reaction tube 2 is exhausted to set the internal pressure of the reaction tube 2 at a predetermined pressure, for example, at 1064 Pa (8 Torr) as illustrated in FIG. 3B (standby step).

The internal temperature of the reaction tube 2 may be 450 to 800 degrees C. By setting the internal temperature of the reaction tube 2 to fall within this range, it is easy to carbon-terminate the surface of the silicon nitride film as formed. This makes it possible to suppress the generation of a natural oxide film.

Furthermore, the internal temperature of the reaction tube 2 may be equal to a film forming temperature of the silicon nitride film. By setting the internal temperature of the reaction tube 2 equal to the film forming temperature, it is easy to control the temperature. This makes it possible to efficiently perform the processing.

The internal pressure of the reaction tube 2 may be set at 0.133 Pa (0.001 Torr) to 13.3 kPa (100 Torr). By setting the internal pressure of the reaction tube 2 to fall within this range, it is easy to carbon-terminate the surface of the silicon nitride film. This makes it possible to suppress the generation of a natural oxide film. More specifically, the internal pressure of the reaction tube 2 may be set at 13.3 Pa (0.1 Torr) to 1.33 kPa (10 Torr), particularly 133 Pa (1 Torr) to 1,064 Pa (8 Torr). By setting the internal pressure of the reaction tube 2 to fall within this range, it is possible to promote the carbon-termination of the surface of the silicon nitride film.

Subsequently, as illustrated in FIG. 3F, ethylene (C₂H₄) is supplied from the process gas supply pipe 21 or the like into the reaction tube 2 at a flow rate of 1 slm (carbon purge step).

The supply amount of ethylene may be set at 10 sccm to 10 slm. If the supply amount of ethylene is smaller than 10 sccm, there is a possibility that the surface of the silicon nitride film cannot be sufficiently carbon-terminated. If the supply amount of ethylene is larger than 10 slm, there is a possibility that the amount of ethylene not contributed to a reaction increases. More specifically, the supply amount of ethylene may be set at 0.1 slm to 10 slm, particularly 0.1 slm to 5 slm. By setting the supply amount of ethylene to fall within this range, it is possible to promote the carbon-termination of the surface of the silicon nitride film.

If the ethylene is supplied into the reaction tube 2, the surface of the silicon nitride film is carbon-terminated. This makes it possible to suppress the generation of a natural oxide film. As a result, it is possible to improve the wet etching resistance of the surface of the silicon nitride film.

After the carbon purge step is completed, the supply of ethylene from the process gas supply pipe 21 or the like is stopped. Then, the gas existing within the reaction tube 2 is exhausted and a predetermined amount of nitrogen is supplied from the process gas supply pipe 21 or the like into the reaction tube 2 as illustrated in FIG. 3C, thereby discharging the gas existing within the reaction tube 2 to the outside of the reaction tube 2 (purge and vacuum step).

Subsequently, the interior of the reaction tube 2 is maintained at a predetermined loading temperature, for example, at 450 degrees C. as illustrated in FIG. 3A, by the heater part 10 and a predetermined amount of nitrogen is supplied from the process gas supply pipe 21 or the like into the reaction tube 2, thereby discharging the gas existing within the reaction tube 2 to the outside of the reaction tube 2 and returning the internal pressure of the reaction tube 2 to the atmospheric pressure (atmospheric pressure return step).

Then, the lid 6 is moved down by the boat elevator 127, thereby unloading the semiconductor wafers W and recovering the semiconductor wafers W from the wafer boat 9 (wafer discharge step). Thus, the processing is completed. Thereafter, the step of forming the silicon nitride film described above may be performed again.

As described above, by performing the carbon purge step after the silicon nitride film is formed on the semiconductor wafer W, it is possible to carbon-terminate the surface of the silicon nitride film. Thus, it is possible to suppress the generation of the natural oxide film. As a result, it is possible to improve the wet etching resistance of the surface of the silicon nitride film.

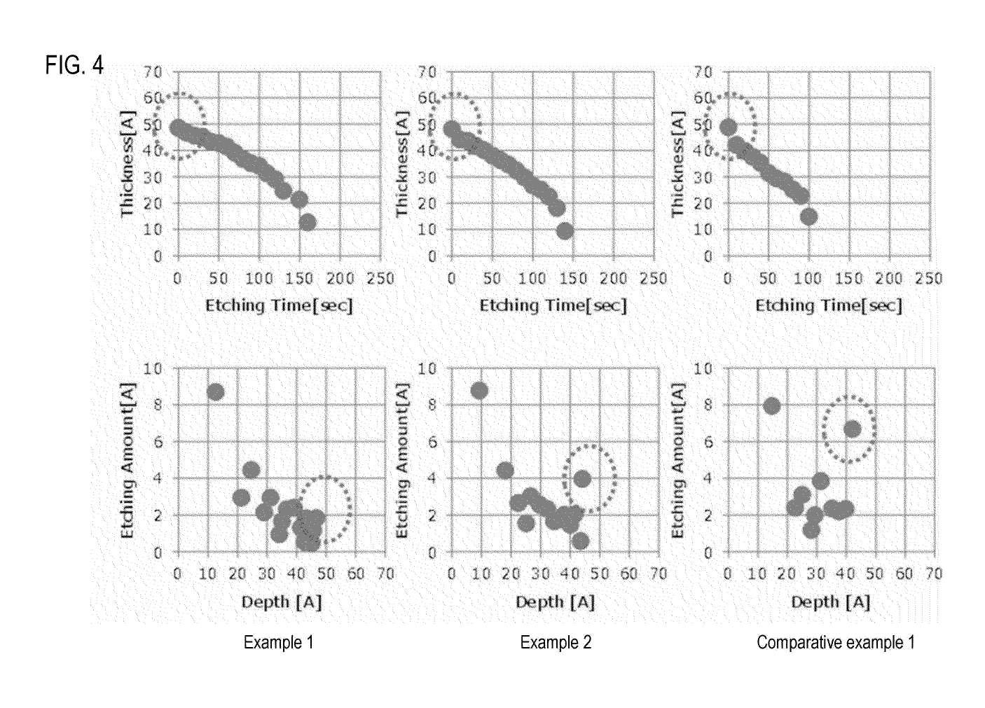

Then, in order to confirm the effects of the present disclosure, the relationship between a thickness and a time and the relationship between a test piece depth and an etching amount were measured in the case where a test piece obtained by forming a silicon oxide film having a thickness of 5 nm (50 Å) on the semiconductor wafer W according to the aforementioned embodiment is etched using buffered hydrogen fluoride (BHF) (Example 1). Furthermore, similar measurements were conducted with respect to a test piece obtained by the same method except that the internal pressure of the reaction tube 2 at the carbon purge step is set at 133 Pa (1 Torr) (Example 2). For the comparison purpose, similar measurements were conducted with respect to a case (Comparative Example 1) where a nitrogen gas is used as a carbon purging gas. The results are shown in FIG. 4.

As indicated in the positions surrounded by broken lines in FIG. 4, it can be noted that the etching amount can be reduced by performing the carbon purge step. Particularly, it can be confirmed that the etching amount is greatly reduced by setting the internal pressure of the reaction tube 2 at 1,064 Pa (8 Torr). This is because, by carbon-terminating the surface of the silicon nitride film, it is possible to suppress the generation of a natural oxide film and, consequently, to improve the wet etching resistance of the surface of the silicon nitride film.

As described above, according to the present embodiment, by performing the carbon purge step after the silicon nitride film forming step, it is possible to carbon-terminate the surface of the silicon nitride film as formed and to suppress the generation of a natural oxide film. As a result, it is possible to improve the wet etching resistance of the surface of the silicon nitride film.

The present disclosure is not limited to the aforementioned embodiment but may be differently modified or applied. Hereinafter, descriptions will be made on other embodiments applicable to the present disclosure.

In the aforementioned embodiment, the present disclosure has been described by taking, as an example, a case where DCS is used as the Si source and ammonia is used as the nitriding gas. However, the Si source and the nitriding gas may be any organic source gas and any nitriding gas capable of forming a silicon nitride film. Various kinds of gases may be used as the Si source and the nitriding gas.

In the aforementioned embodiment, the present disclosure has been described by taking, as an example, a case where the silicon nitride film is formed on the semiconductor wafer W by performing 100 cycles. However, the number of cycles may be reduced to, for example, 50 cycles. Alternatively, the number of cycles may be increased to, for example, 200 cycles. Even in these cases, a silicon nitride film having a desired thickness can be formed by adjusting, for example, the supply amounts of the Si source and ammonia, in a corresponding relationship with the cycle numbers.

In the aforementioned embodiment, the present disclosure has been described by taking, as an example, a case where the silicon nitride film is formed on the semiconductor wafer W using the ALD method. However, the present disclosure is not limited to the case of using the ALD method. The silicon nitride film may be formed on the semiconductor wafer W using a CVD method.

In the aforementioned embodiment, the present disclosure has been described by taking, as an example, a case where nitrogen as a dilution gas is supplied when supplying the source gas and the nitriding gas. However, nitrogen may not be supplied when supplying the source gas and the nitriding gas. If nitrogen is included as the dilution gas, it becomes easy to set the processing time or the like. It is therefore advisable that the dilution gas is included. The dilution gas may be an inert gas. In addition to nitrogen, for example, helium (He), neon (Ne), argon (Ar), krypton (Kr) or xenon (Xe) may be used as the dilution gas.

In the aforementioned embodiment, the present disclosure has been described by taking, as an example, a case where the film forming apparatus is a batch-type processing apparatus having a single tube structure. However, the present disclosure is applicable to, for example, a batch-type processing apparatus having a dual tube structure. Furthermore, the present disclosure may be applied to a batch-type horizontal processing apparatus or a single-substrate-type processing apparatus. Moreover, the workpiece is not limited to the semiconductor wafer W but may be, for example, a glass substrate for liquid crystal display (LCD).

The control part 100 according to the embodiment of the present disclosure may be realized using a typical computer system without resorting to a dedicated system. For example, the control part 100 which performs the aforementioned processing may be configured by installing a program for executing the aforementioned processing onto a general-purpose computer from a recording medium (a flexible disc, a compact disc read only memory (CD-ROM), or the like) which stores the program.

Means for supplying the program is arbitrary. The grogram may be supplied not only through a specified recording medium as described above but also through, for example, a communication line, a communication network, a communication system or the like. In this case, for example, the program may be posted to a bulletin board system (BBS) of a communication network and may be provided through a network. The aforementioned processing may be performed by starting up the program thus provided and executing the program under the control of an operating system (OS) in the same operating method as that of other application programs.

The present disclosure is useful in a silicon nitride film forming method and a film forming apparatus.

According to the present disclosure in some embodiments, it is possible to improve a wet etching resistance.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A silicon nitride film forming method, comprising:
accommodating a workpiece within a reaction chamber;
forming a silicon nitride film on the workpiece accommodated within the reaction chamber;
carbon-terminating a surface of the silicon nitride film by supplying a hydrocarbon compound having an unsaturated bond into the reaction chamber accommodating the workpiece on which the silicon nitride film is formed; and
unloading the workpiece, on which the silicon nitride film having a carbon-terminated surface is formed, out of the reaction chamber.

2. The method of claim 1, wherein the hydrocarbon compound having the unsaturated bond is a compound selected from a group consisting of ethylene, propylene and acetylene.

3. The method of claim 1, wherein, in the forming the silicon nitride film and the carbon-terminating the surface, the reaction chamber is heated to a temperature of 450 to 800 degrees C.

4. The method of claim 1, wherein, in the carbon-terminating the surface, an internal pressure of the reaction chamber is maintained at 13.3 Pa to 1.33 kPa.

5. The method of claim 1, wherein, in the carbon-terminating the surface, a carbon-containing gas is supplied into the reaction chamber at a flow rate of 0.1 slm to 10 slm.

6. A silicon nitride film forming apparatus, comprising:
a reaction chamber configured to accommodate a workpiece;
a film forming gas supply part configured to supply a film forming gas into the reaction chamber;
a carbon gas supply part configured to supply a hydrocarbon compound having an unsaturated bond into the reaction chamber; and
a control part configured to control the film forming gas supply part and the carbon gas supply part,
wherein the control part is configured to have the workpiece accommodated within the reaction chamber, control the film forming gas supply part to form a silicon nitride film on the workpiece accommodated within the reaction chamber, control the carbon gas supply part to carbon-terminate a surface of the silicon nitride film, and unload the workpiece, on which the silicon nitride film having a carbon-terminated surface is formed, out of the reaction chamber.
